(19) United States
(12) Patent Application Publication
(10) Pub. No.: US 2018/0151885 A1
(43) Pub. Date: May 31, 2018

(54) DISCRETE CARBON NANOTUBES AND MICROFIBER COMPOSITES

(71) Applicant: MOLECULAR REBAR DESIGN LLC, Austin, TX (US)

(72) Inventors: Clive P. Bosnyak, Dripping Springs, TX (US); Malcolm Francis Finlayson, Houston, TX (US); Matthew James Jungman, Austin, TX (US); Jerzy Gazda, Austin, TX (US); Vinay Bhat, Austin, TX (US)

(73) Assignee: MOLECULAR REBAR DESIGN LLC, Austin, TX (US)

(21) Appl. No.: 15/825,754

(22) Filed: Nov. 29, 2017

Related U.S. Application Data
(60) Provisional application No. 62/428,268, filed on Nov. 30, 2016.

(51) Int. Cl. H01M 4/62; C09D 11/52; C09D 11/037; C09D 5/24; C09D 109/08; C09D 7/40; H01L 51/00; H01M 4/587; H01M 10/0525

(52) U.S. Cl. CPC H01M 4/625; C09D 11/52; C09D 11/037; C09D 5/24; B82Y 40/00; C09D 7/70; H01L 51/0049; H01M 4/587; H01M 10/0525; C09D 109/08

(57) ABSTRACT

A composition comprising discrete functionalized carbon nanotubes attached to microfibrillated fibers and a plurality of the discrete carbon nanotubes are opened ended is disclosed. The composition may further comprise electroactive, photoactive, magnetic or catalyst particles. These new compositions can be used in energy storage or energy collection devices such as batteries, capacitors, photovoltaics and sensors.

### CROSS REFERENCE TO RELATED APPLICATIONS

This application claims priority from U.S. Provisional Application 62/428,628 filed Nov. 30, 2016, and is related to U.S. Ser. No. 13/164,456, filed Jun. 20, 2011, and its progeny; and U.S. Ser. No. 13/140,029, filed Aug. 9, 2011, and its progeny, the disclosures of each of which is incorporated herein by reference.

### FIELD OF INVENTION

The present invention relates generally to the field of improved technologies for energy storage and energy collection devices.

### BACKGROUND OF THE INVENTION

Energy storage and collection devices, such as batteries, supercapacitors, fuel cells, sensors, and photovoltaics, may be improved by incorporating nanoscale particles, nanoparticles, in combination with microscale particles, microparticles, into the structure of electrodes. Such devices are subject to less than theoretical energy conversion efficiency, or energy capacity because of defects in the active material structures of the electrodes that reduce electrical or ion conductivity. These defects may be present on formation of the electrodes or develop with time and during use.

Lithium ion batteries often exemplify the challenges with maintaining particulate mechanical, ionic and electrical connectivity in porous media with disparate size scales of the particles and associated pores, particularly during swelling and shrinkage of particles associated with mechanical or electrochemical activity. In addition, the disparate size scales of the particles lead to non-homogenous dispersion of the nanoparticles in the presence of the microparticles. The inability to overcome the issues associated with the multimodal spatial distances leads to reduced power, cycling life span and capacity in batteries. It may also limit the ability to increase the electrode thickness and energy density. Thus it is very challenging to reach an improvement in a combination of performances such as paste rheology for electrode formation, ion transport, electron conductivity, adhesion and mechanical integrity.

### SUMMARY OF THE INVENTION

One aspect of the present application is a composition comprising discrete functionalized carbon nanotubes, preferably a plurality of functionalized discrete carbon nanotubes, attached to microfibrillated fibers wherein the discrete functionalized carbon nanotubes are attached to the microfibrillated fibers covalently, ionically or electrostatically and a plurality of the discrete functionalized carbon nanotubes are open ended.

In certain embodiments, the microfibrillated fibers are microfibrillated organic microfibers, preferably of polymer, biological or plant source. Microfibrillated fibers can also be sourced from inorganic and synthetic materials. Microfibrillated fiber can have the morphology of a multi-branched fiber or webbed fiber.

In some embodiments, the plurality of the microfibers have an average length from about 0.05 micrometers to about 1000 micrometers, preferably from about 0.1 micrometers to about 300 micrometers and more preferably from about 3 micrometers to about 75 micrometers.

In another embodiment a plurality of the microfibrillated fibers are at least about 10 times the average length of the discrete carbon nanotubes.

Another aspect of the present application is a composition further comprises a particle, preferably a nanoparticle. The nanoparticle can be particles having at least one dimension of less than about 1 micrometer. Preferably having at least one dimension of less than about 500 nanometers, more preferably less than about 250 nanometers. The nanoparticle can be of any shape and can include spheroid, plate-like, obloid or rod.

In another embodiment the nanoparticle is an electroactive nanoparticle. The electroactive nanoparticle is a chemical compound or a mixture of chemical compounds that participate in a reaction or process involving electron exchange. Electroactive particles are used in batteries, electrochemical, thermoelectric, electrochromic, piezoelectric, and other devices. For example, lithium ion battery is an electrochemical device. Lithium ion battery cells contain electrodes. These electrodes comprise electroactive particles that take part in electrochemical reactions. Electrochemical reactions involve exchange of ions and electrons during storage and retrieval of energy. The electroactive nanoparticle can comprise a lithium intercalating compound or a lithium alloying compound.

In another embodiment the nanoparticle is a magnetic particle. The magnetic particle is capable of being manipulated by magnetic fields. The magnetic particle can be paramagnetic or superparamagnetic.

In yet another embodiment the particle is a catalyst.

In yet another embodiment the particle is a photoactive particle.

Another embodiment of the present invention is a composition that further comprises an electrolyte. In certain embodiments, the electrolyte is an electrically insulating medium that transport ions between electrodes. In certain embodiments, the electrolyte can be a liquid, gel, solid or a combination thereof. Liquid electrolytes can contain organic solvents, inorganic solvents or ionic liquids with salts and other optional components. Solid electrolytes are those electrolytes that are solid at room temperature and can contain crystalline or amorphous materials. Gel electrolytes can be an intermediate phase between liquid and solid or a combination of liquid and solid phases.

Another embodiment of the present invention is a composition that further comprises a polymer. In certain embodiments, the polymer may impart adhesive or cohesive properties on the composition. In certain embodiments, the polymer may be ion conductive polymer. In certain embodiments, the polymer may be ion selective polymer. In certain embodiments, the polymer may be a ionophore. In certain embodiments, the polymer may be a chromophore. Further, in certain embodiments, the polymer may be chromoionophoric or electrochromic.

In yet another embodiment of this invention is a composition further comprising a surfactant selected from the group consisting of anionic, cationic, non-ionic and zwitterionic surfactants.

In yet another embodiment, the composition is a film or membrane. The composition is a fiber, thread, or a filament.

In further embodiments, the composition of the present invention may comprise carbon nanotubes which are functionalized with oxygen species selected from the group consisting of carboxylic acids, phenols, lactols, lactones, aldehydes, ketones, ether linkages, and combinations thereof. The functionalization may include attachment of solid electrolyte interphase mediators selected from carbonates, fluorides, phosphates, salicylates, oxides, hydroxides, amides, sulfates, nitrates, and combinations thereof. The functionalization may include attachment of dyes. The functionalization may include a metal. The functionalization may include a drug molecule, radiotherapy molecule, protein molecule, and combinations thereof.

In further embodiments, the composition can further comprise carbon allotropes. The carbon allotropes include, but not limited to, graphene, graphite, graphene oxide, reduced graphene oxide, carbon black, oxidized carbon black, fullerenes, carbon fibers and combinations thereof.

The composition can be a fluid medium. The fluid medium can be aqueous or non-aqueous. The fluid together with the functionalized discrete carbon nanotubes attached to microfibers, optionally further comprising nanoparticles, may be an electrorheological fluid or magnetorheological fluid.

In further embodiments, the composition is a conductive ink.

In certain embodiments, the composition is an electrode paste.

In certain embodiments, the composition is electromagnetic shielding.

In certain embodiments, the composition is a sensor. The sensor may detect electrons, electromagnetic, magnetic, thermal, photonic, mechanical, chemical or biological inputs or moieties.

One aspect of the present application relates to a composition comprising microfibrillated cellulose, nanoparticles and microparticles. A plurality of the nanoparticles has at least one dimension of size ranging from about 2 to 1000 nanometers, more preferably from about 10 to about 500 nanometers, and more preferably from about 20 to about 250 nanometers. The nanoparticles can be electroactive particles of a lithium intercalating compound. A plurality of microparticles has a size range from about 0.5 to about 25 micrometers, more preferably from about 1 to about 15 micrometers, and more preferably from about 3 to about 10 micrometers. The microparticles are carbon allotropes selected from but not limited to, graphite, carbon black agglomerates, oxidized carbon black agglomerates, carbon fibers and combinations thereof.

Another aspect of this invention is a spatial network of microfibrillated fibers that enables stabilization in space of a combination of plurality of types and sizes of nanoparticles, for example, comprising a mixture of conductive nanoparticles and active nanoparticles, lithium intercalating nanoparticles, and microparticles, that could, for example, be lithium intercalating or alloying. This allows for creation of a multiscale network that is conductive to electrons, while it also provides a fast diffusion path, due to high surface area, to ionic species, such as Li ions in lithium ion battery anodes. Therefore, the created network with microfibrillated fibers enhances electrode conductivity to both ions and electrons. Additionally the created network can impart additional strength to the electrode composite and additional adhesion to electrode current collectors that result in extended cycle life of energy storage or collection device.

In certain embodiments, the composition is dispersed in a fluid. In certain embodiments, the composition is dispersed in a paste. In certain embodiments, the composition is dispersed in an anode or cathode formulation.

In other embodiments, the discrete carbon nanotubes disclosed herein and formulations thereof can be used in, or comprise a component of, super capacitors, photovoltaics, replacements for hyaluronic acid and synovial fluid, structures or scaffolding for stem cell growth, and electromagnetic interference (EMI) and/or radio frequency (RF) shielding and/or static dissipation.

### BRIEF DESCRIPTION OF THE DRAWINGS

The following figures are for purposes of illustration of select embodiments only and are in no way limiting upon the invention herein.

FIG. 1 shows an electron micrograph of discrete functionalized carbon nanotubes attached to microfibrillated cellulose in a lithiated polyacrylic acid binder bridging microparticles of graphite and nanoparticles of silicon as an anode for use in a lithium ion battery.

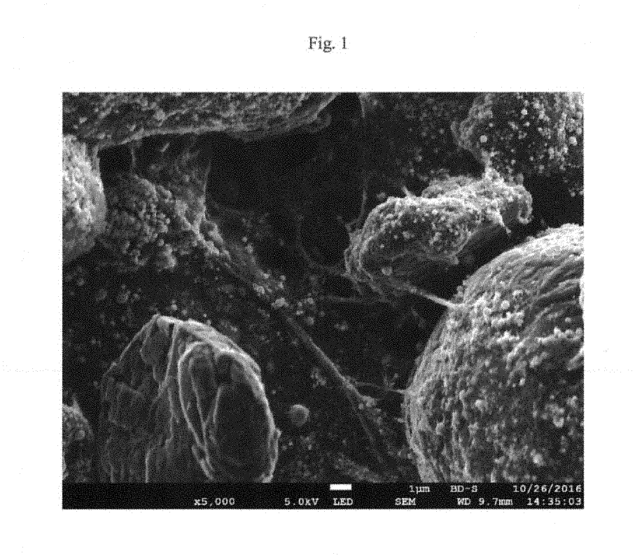

FIG. 2 shows an electron micrograph of discrete functionalized carbon nanotubes attached to microfibrillated cellulose in a lithiated polyacrylic acid binder bridging microparticles of graphite and nanoparticles of silicon as an anode for use in a lithium ion battery.

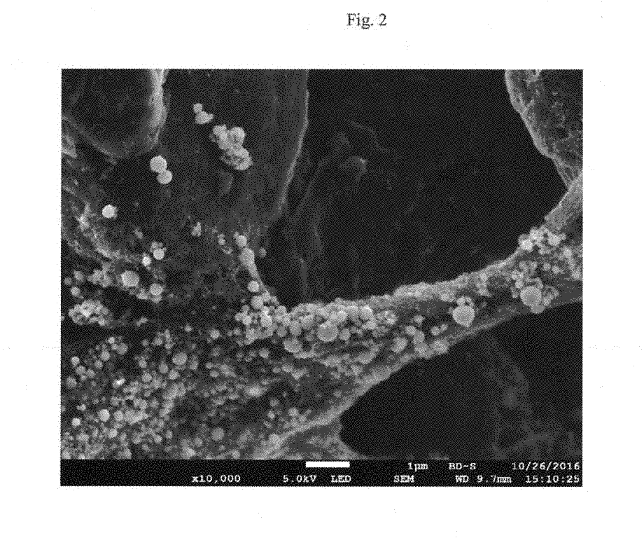

FIGS. 3A and 3B show discrete carbon nanotubes compositions. FIG. 3A shows discrete carbon nanotubes, Si nanoparticles, graphite microparticles and lithiated PAA binder. FIG. 3B shows discrete carbon nanotubes, MFC, Si nanoparticles, graphite microparticles and lithiated PAA binder. Comparison of FIGS. 3A and 3B shows that MFC significantly improves the homogeneity of dispersion of the silicon nanoparticles.

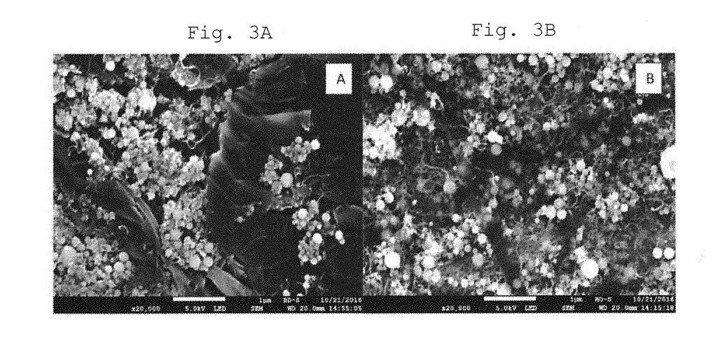

FIGS. 4A and 4B show electron micrographs of discrete functionalized carbon nanotubes attached to microfibrillated cellulose in lithiated polyacrylic acid binder bridging microparticles of graphite and nanoparticles of silicon as an anode for use in a lithium ion battery. FIG. 4A shows 2500× magnification while FIG. 4B shows 5000× magnification.

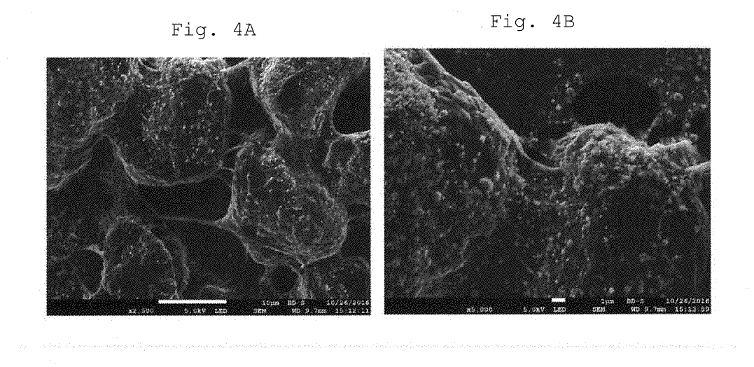

### DETAILED DESCRIPTION

In the following description, certain details are set forth such as specific quantities, sizes, etc., so as to provide a thorough understanding of the present embodiments disclosed herein. However, it will be evident to those of ordinary skill in the art that the present disclosure may be practiced without such specific details. In many cases, details concerning such considerations and the like have been omitted inasmuch as such details are not necessary to obtain a complete understanding of the present disclosure and are within the skills of persons of ordinary skill in the relevant art.

While most of the terms used herein will be recognizable to those of ordinary skill in the art, it should be understood, that when not explicitly defined, terms should be interpreted as adopting a meaning presently accepted by those of ordinary skill in the art. In cases where the construction of a term would render it meaningless or essentially meaningless, the definition should be taken from Webster's Dictionary, 3rd Edition, 2009. Definitions and/or interpretations should not be incorporated from other patent applications, patents or publications, related or not unless specifically stated in this specification.

### Carbon Nanotubes

As-made carbon nanotubes using metal catalysts such as iron, aluminum or cobalt can retain a significant amount of the catalyst associated or entrapped within the carbon nanotube, as much as five weight percent or more. These residual metals can be deleterious in such applications as electronic devices because of enhanced corrosion or can interfere with the vulcanization process in curing elastomer composites. Furthermore, these divalent or multivalent metal ions can associate with carboxylic acid groups on the carbon nanotube and interfere with the discretization of the carbon nanotubes in subsequent dispersion processes. In other embodiments, the oxidized carbon nanotubes comprise a residual metal concentration of less than about 25000 parts per million (ppm), and preferably less than about 5000 parts per million. The metals can be conveniently determined using atomic emission spectroscopy, energy dispersive X-ray spectroscopy or thermogravimetric methods.

As manufactured carbon nanotubes are in the form of bundles or entangled agglomerates and can be obtained from different sources, such as Nanocyl, Arkema, CNano Technology and Kumho Petrochemical, to make discrete carbon nanotubes. An acid solution, preferably nitric acid solution at greater than about 60 weight % concentration, more preferably above 65% nitric acid concentration, can be used in conjunction with shear force-to make the discrete tubes. Mixed acid systems (e.g. nitric and sulfuric acid) as disclosed in US 2012-0183770 A1 and US 2011-0294013 A1, the disclosures of which are incorporated herein by reference, can be used to produce discrete, oxidized carbon nanotubes from as-made bundled or entangled carbon nanotubes.

During the process of making discrete or exfoliated carbon nanotubes (which can be single, double and multiwall configurations), the nanotubes are cut into segments with at least one open end and residual catalyst particles removed. The cutting of the tubes helps with exfoliation. The bundled carbon nanotubes can be made from any known means such as, for example, chemical vapor deposition, laser ablation, and high pressure carbon monoxide syntheses. The bundled carbon nanotubes can be present in a variety of forms including, for example, soot, powder, fibers and bucky paper. Furthermore, the bundled carbon nanotubes may be of any length, diameter or chirality. Carbon nanotubes may be metallic, semi-metallic, semi-conducting, or non-metallic based on their chirality and number of walls. Proper selection of the carbon nanotube feedstock related to catalyst particle type and distribution in the carbon nanotubes allows more control over the resulting individual tube lengths and overall tube length distribution.

In a preferred embodiment, the internal catalyst sites are evenly spaced and where the catalyst is most efficient. The preferred aspect ratio (length to diameter ratio) is greater than about 25 and less than about 200 for balance of viscosity and performances. The plurality of discrete functionalized open ended multi-wall carbon nanotubes preferably comprises tube lengths of varying lengths. The tube length distribution may be monomodal, bimodal or multimodal. For tube length distributions comprising at least 2 groups of lengths, preferred is wherein each group's tube length varies on average by at least about 10% from the other group's average tube length. Different length distributions may utilized to match the other structures of the invention, including distances between nanoparticles, length of the microfibrillated fibers, degree of branching of the microfibrillated fibers, distances between nanoparticles, size of the nanoparticles or combinations thereof.

The discrete carbon nanotubes (dCNT) of the formulation can comprise L/D of about 100 to 200 and about 30% or more of the discrete carbon nanotubes of the formulation can comprise L/D of 40 to 80, with the average L/D of the discrete carbon nanotubes (dCNT) of the formulation being from about 50 to about 75, preferably about 65. The L/D of the discrete carbon nanotubes can be a unimodal distribution, or a multimodal distribution (such as a bimodal distribution). The multimodal distributions can have evenly distributed ranges of aspect ratios (such as 50% of one L/D range and about 50% of another L/D range). The distributions can also be asymmetrical—meaning that a relatively small percent of discrete nanotubes can have a specific L/D while a greater amount can comprise another aspect ratio distribution.

### Functionalization of Carbon Nanotubes

Functionalized carbon nanotubes of the present disclosure generally refer to the chemical modification of any of the carbon nanotube types described hereinabove. Such modifications can involve the nanotube ends, sidewalls, interior or combination thereof. Chemical modifications may include, but are not limited to covalent bonding, ionic bonding, chemisorption, intercalation, surfactant interactions, polymer wrapping, cutting, solvation, and combinations thereof.

The functionalization can include oxygen species selected from the group consisting of carboxylic acids, phenols, aldehydes, lactols, lactones, ketones, ether linkages and combinations thereof. Further functionalization can be obtained by reactions with the oxygen species. One example is ion exchange of the carboxyl group with metals to form ionomer type carboxy-metal bonds. Another example is the reaction of the phenolic groups.

The functionalization can include attachment of solid electrolyte interphase (SEI) mediators. Examples of SEI mediators can include carbonates, fluorides, phosphates, sulfates, esters, salicilics, lithium salts and combinations thereof.

The plurality of functionalized discrete open ended multi-wall carbon nanotubes comprises an average aspect ratio of from about 25 to about 200, preferably 25-150 and most preferably 40-120.

The plurality of functionalized discrete open ended multi-wall carbon nanotubes can comprise about 0.01 to about 99% by weight of the formulation, preferably about 0.1 to about 99, more preferably about 0.25 to about 95% by weight of the formulation.

### Microfibrillated Fibers

Microfibrillated fibers are fibers that have been fibrillated, where the base fiber has been split into a higher number of thinner fibers. Microfibrillated fiber can have the morphology of a multi-branched fiber or webbed fiber or a combination. Microfibrillated fibers can be sourced from plant derived natural fibers such as wood, plant stalks, cotton or other fibrous plant material. Plant derived microfibrillated fibers can include microfibrillated cellulose (MFC). Microfibrillated fibers can be sourced from synthetic materials such as glass, polymers, metals, metal alloys. Microfibrillated fibers can be sourced from animal derived natural fibers such as silk, hair or fur.

The three dimensional network of thin fiber webs and branches extending from long microfibrillated fibers creates bridges between the nano-scale particles and simultaneous contact with the larger, more distance active material. This spatial network provides a strengthening mechanism to a paste composite.

Microfibrillated fibers can be split into fibers that have diameters substantially smaller than 1 micrometer, such fibers are also known as nano-fibrillated.

Preferred embodiments are micro-fibers split into smaller-diameter fibers with a highly branched structure in which the diameters of the main fiber stems are in the range of about 10 nanometers to about five (5) micrometers. In other suitable embodiments, micro-fibers are split into smaller-diameter fibers in which the diameters of the main fiber stems are in the range of about 5 nanometers to about fifty micrometers. In other embodiments, other diameter main fibers with smaller-diameter fibers with highly branched structures are included.

In another preferred embodiment micro-fibers have a highly branched structure in which the main fiber stems length distribution is in the range of about 3 to about 75 micrometers. Suitable microfibers are fibers with main fiber stems length distribution in the range of about 0.1 to about 300 micrometers. Other micro-fibers with average lengths main stems in the range of about 0.05 micrometers to about one thousand micrometers are included.

Microfibrillated fibers are commercially available from various sources. Nano-fibrillated and microfibrillated cellulose (MFC), or cellulose nanofibrils (CNF) are commercially available from FiberLean Technologies (Omya), Carolina Cellulose, PaperLogic, Nippon Paper, CelluForce, American Process Inc., BASF, Zelfo Technologies, Borreggard, Weidmann, Daicel Finechem Ltd., and others.

Microfibrillated fibers are produced by various methods. Preferred method for preparation of microfibrillated fibers from un-branched or plain fibers is to place the plain fibers under high fluid pressure and to quickly release the pressure. Suitable method of preparation of microfibrillated fibers is to subject the pulp to homogenization process by mixing, grinding or any high mechanical shear processing. Other methods known to those versed in the art are thereby incorporated.

Microfibrillated fibers can be sourced from plant derived natural fibers. Plant derived micro-fibrillated fibers comprise microfibrillated cellulose (MFC). Micro-fibrillated fibers can be sourced from animal derived natural fibers such as silk, hair or fur. Micro-fibrillated fibers can be sourced from synthetic materials such as glass, polymers, metals, metal alloys. One of ordinary skill in the art will recognize that many of the specific aspects of this invention illustrated utilizing a particular type of microfibrillated fiber may be practiced equivalently within the spirit and scope of the disclosure utilizing other types of micro-fibrillated fibers.

Preferred microfibrillated fibers comprise MFC of plant sourced cellulose. Other suitable microfibrillated fibers further comprise synthetic reconstituted cellulose such as rayon, viscose, modal, or tencel.

Other suitable microfibrillated fibers include: polysaccharide derivatives such as dextran, or polyacrylonitrile (PAN), or fibers comprising polymers and organic materials such as: polyethylene terephthalate (PET), larger-diameter carbon nanofibers (CNFs), polyester, polyurethane, polybutylene terephthalate, poly(lactic acid), polytrimethylene terephthalate, nylon 6, nylon 66, polyolefin and polyphenylene sulfide or propylene/α-olefin, or other suitable fibrillated combinations thereof. Thermoplastic materials include (but are not limited to) the following: polyamideimide, polyethersulphone, polyetherimide, polyarylate, polysulphone, polyamide (amorphous), acrylate polymers (such as polymethylmethacrylate, polybutylacrylate, polyethylmethacrylate), polyvinylchloride, styrene acrylonitrile (SAN), acrylonitrile butadiene styrene (ABS), polystyrene, polyetheretherketone, polytetrafluoroethylene, polyamides (such as polyamide 6,6, polyamide 11, polyamide 6), polyphenylene sulphide, polyethylene terephthalate, polybutylene terephthalate, polyoxymethylene, polystyrene, polypropylene, high density polyethylene, low density polyethylene, linear low density polyethylene, ultra low density polyethylene, olefin type elastomers, natural rubber, polybutadiene, neoprene, polydimethylsiloxane, polyoxymethylene, polycarbonate, polyetherketone, polysulfone, polyphenylene sulfide, polyethersulfone, polyetherimide, polytetrafluoroethylene, polyethylene vinyl acetate, polyvinyl alcohol, poly(ethylene-co-vinyl alcohol) (EVA), poly(ethylene co-acrylic acid) (EAA), polyethylene co-carbon monoxide (ECO), cellulosics and others and combinations thereof. Thermoplastics may contain plasticizers, antioxidants and other additives.

The polymer can be a thermoset polymer. Thermoset polymers include but not limited to allyl resins, alkyds, epoxies, furans, melamine formaldehyde, phenol-formaldehyde (phenolic), polyimide, unsaturated polyester, polyurethane, vinyl esters, silicone and combinations thereof. It will be clear to one of ordinary skill in the art that the microfibrillated fibers of one polymer can be used in a blend as a component with a second polymer which is different from the first polymer. In such an instance the microfibrillated fibers can be seen as a reinforcement of the non-fibrillated polymer. In the case of microfibrillated fibers with attached carbon nanotubes being used as a blend component as described above, the branched network offers a conductive pathway of ions or electrons through the electrically insulating host matrix polymer. Suitable microfibrillated fibers can be sourced from plants, including abacá, bagasse, bamboo, beach, boir, cotton, fique, flax, linen, hemp, jute, kapok, kenaf, piña, pine, raffia, ramie, rattan, sisal, spruce, and other wood species.

Suitable microfibrillated fibers can be sourced from animals including alpaca, angora, byssus, camel hair, cashmere, catgut, chiengora, guanaco hair, llama, mohair, pashmina, qiviut, rabbit, silk, tendon, spider silk, wool, vicuña, yak;

Suitable microfibrillated fibers can be derived from asbestos, wurtzite, quartzite.

Suitable microfibrillated fibers can be derived from art silk, semi-synthetic: acetate, diacetate, lyocell, modal, rayon, triacetate.

Suitable microfibrillated fibers can be synthetic fibers derived from: glass, carbon, basalt, metallic elements or alloys or compounds containing metallic elements.

Suitable microfibrillated fibers can be derived from a single polymer or a combination of polymers, including acrylic, aramid, twaron, kevlar, Technora, Nomex, Modacrylic, nylon, olefin, polyester, polyethylene, Dyneema, Spectra, spandex, vinylon, vinyon, zylon.

Suitable microfibrillated fibers can include aggregates and mixtures of nanofibers, microfibers, and micro-fibrillated fibers.

### Nanoparticles

The nanoparticle geometries can include plate like structures with a single or few layers such as graphene, graphene oxide, reduced graphene oxide, flake graphite, flake silicon, calcium hydroxyapatite and mica sheets. The graphene can be obtained from XG Sciences. Suppliers of graphene oxide or reduced graphene oxide include Graphenea.

The nanoparticles may be comprised of elements, or mixtures of elements, including but not limited to: B, Al, Ga, In, Si, Ge, Sn, N, P, As, Sb, O, S, Te, Se, F, Cl, Br, I, Ti, Zr, Hf, V, Nb, Ta, Cr, Mo, W, Mn, Re, Fe, Ru, Os, Co, Rh, Ir, Ni, Pd, Pt, Ag, Cu, Au, Zn, Cd, lanthanides, and actinides, SnO₂, TiO₂, SiO₂ and other oxides, phosphates, and sulfides, BaSO₄, PbSO₄, Ag₂SO₄ and SrSO₄, CdS, FeS, ZnS, Ag₂S are included. In addition, nanoparticles soluble in water, but stable in other solvents are included or may be included.

The composition of nanoparticles may comprise nanoplates and nanotubes further comprising at least one transition metal complex or active catalyst species. An active catalyst can be ionically, or covalently attached to the discrete nanotubes, or inorganic plates or combinations thereof. The chemical reactions can involve contact of the composition with, for example, but not limited to, alkenes and alkynes, chemical moieties containing oxygen, chemical moieties containing nitrogen, chemical moieties containing halogen, and chemical moieties containing phosphorous. The composition may be in the form of a powder for gas phase reaction or in the form of a liquid mixture for solution and slurry phase reactions.

The nanoparticle may be an amorphous alloy or agglomerate of metallic and organic phases, metals, compounds, alloys, intermetallics, or solid-solutions and may be conductors, or semiconductors of p-type or n-type

The catalyst nanoparticle may comprise a composition of pure metals, metal alloys, and compounds containing sub-crystallites of metallic materials and combination of inorganic and organic compounds and metal nanoparticles. The catalyst nanoparticle may comprise transition metals selected from the elements Ru, Rh, Pt, Ir, Pd, Au, Ni, Fe, Ag, vanadium, Ti, alloys of those metals, and compounds of such or by other catalyst known to those versed in the art may be used. Multifunctional solids comprising catalytically active phase such as zeolites, alumina, titania, higher-order oxides, alone or in combination with graphitic carbon are included. In some embodiments, the catalysts are suitable for use in fuel cells, or electrochemical reformers, or for use in hydrocarbon cracking.

The nanoparticles may be magnetic nanoparticles. Magnetic nanoparticles are defined herein as nanoparticles that can be manipulated using magnetic fields. Such particles may consist of a plurality of components. Such particles may comprise a magnetic material comprising one or more elements selected from the group of iron, nickel, manganese, cobalt, dysprosium, niobium, or holmium containing components and a chemical component that has functionality.

The functionalization of magnetic nanoparticles can include oxides, carboxylates, amines, amides, proteins, silicon, carbon and also the magnetic particles may consist of layers, blends or crystals of the magnetic components. The particles can multimodal, unimodal in one dimension and can be a single particle or agglomerated particles.

The composition of nanoparticles can comprise a superconducting material.

### Polymer

In certain embodiments, the polymer may be a binder. Binders include polyacrylic acid (PAA), poly(styrene butadiene), carboxymethylcellulose (CMC), styrene-butadiene (SBR) and polyvinylidene fluoride (PVDF). These binders are used to hold the active material particles together and maintain contact with the current collectors, for example, Al or Cu foil in lithium ion batteries. The microfibrillated fibers added to a binder system of an electrode will improve the mechanical strength of the binder, improve resilience and reduce cracking due to dimensional changes. The microfibrillated fibers (MFF) will increase the storage modulus of the binder keeping particles suspended during the drying process. Maintaining the suspension of particles can maintain the homogeneity of the dispersion of nanoparticles and microparticles while solvent is removed from the paste. With microfibrillated cellulose fibers, MFC, the improvement in adhesion to metals such as copper, aluminum and nickel is found to require unexpectedly small amounts of MFC, for example from about 0.1% to about 30% by weight of MFC. The addition of the microfibrillated fibers increases the viscosity of the electrode paste or ink but in the preferred binder systems for lithium ion battery electrodes the viscosity decreases significantly with shear. This is useful in the pasting process of lithium batteries as well as other wet applications such as inks, paints and other pastes in that the material can easily be spread, sprayed, painted, or rolled onto a surface. The material is also thixotropic in that the suspension of fibers in the binder will return to a high viscosity quickly when shearing is ceased. This is advantageous in that the paste, ink or paint will thicken sufficiently to maintain suspension of any nanoparticles or microparticles when transporting from coater to drier and during drying process, preventing migration of nanoparticles within the coating.

### Effects of Microfibrillated Fibers

Microfibrillated fibers such as MFC can also decrease the drying time of both aqueous and non-aqueous binders system due to wicking of solvent along the branches of the microfibrillated fibers.

Microfibrillated fibers such as MFC can also improve the wetting time of electrolyte in a lithium-ion battery due to wicking of electrolyte along the branches of the microfibrillated fibers. This is useful in reducing the overall time required to produce a fully functioning lithium ion battery.

The degree of branching of the microfibrillated fibers can be varied to obtain the desired viscosity, suspension of particles and adhesion. A higher degree of branching generally leads to a higher viscosity at a given solids content of the fluid.

Microfibrillated fibers such as microfibrillated cellulose, MFC, will sequester nanoparticles to the small fibers keeping the nanoparticles in a non-aggregated state. In a system that includes macromolecules, the uniform distribution of both nanoparticles and macromolecules are maintained by the microfibrillated fibers.

The microfibrillated fibers are made conductive by, for example, the attachment of discrete functionalized carbon nanotubes to the microfibrillated fibers. The discrete functionalized carbon nanotubes (dfCNT) can be attached by covalent, ionic or electrostatic bonds. This imparts electrical conductivity to nonconductive microfibrillated fibers such as MFC. A plurality of the nanotubes are preferably open-ended, and more preferably a plurality of the nanotubes are open-ended at both ends. Open-ended and functionalized nanotubes are preferred for enhanced ion transport.

The attachment of the dfCNT to the microfibrillated fibers can be facilitated with a surfactant.

Examples of the improved electronic conductivity achieved by attachment of dfCNT to the microfibrillated cellulose are provided in Table 1 below.

TABLE 1

| | | | MFC/dfCNT | Resistance |
|---|---|---|---|---|
| Sample | MFC source | Description | (wt. ratio) | (ohms) |
| MFC-1 | Weideman | No dfCNT | Not | >20 × 10⁶ |
| | Q_Adv HAR | | Applicable | |
| MFC-2 | Weideman | dfCNT -CMC | 5/1 | 130 |
| | Q_Adv HAR | Dispersion | | |
| MFC-3 | Weideman | dfCNT - PSS | 5/1 | 70 |
| | Q_Adv HAR | Dispersion | | |
| MFC-4 | Borregard | dfCNT - PSS | 5/1 | 70 |
| | (Forte) | Dispersion | | |

Samples for the study are prepared by drying dispersions of MFC mixed with dfCNT surfactant dispersions (either polystyrene sulfonate, PSS, or carboxymethylcellulose, CMC) in a drying chamber at 100° C. until constant weight is achieved. A standard digital multimeter is used to probe the resistance of the dried samples. The dfCNT surfactant dispersions are prepared by blending dfCNT in water with either polystyrene sulfonate (e.g. sulfonated polystyrene (Polysciences), sodium salt, 70K Mw) or low molecular weight carboxymethylcellulose (e.g. Walocel C from The Dow Chemical Company) under high shear conditions. The dfCNT concentration in the surfactant dispersions is 3% by weight. The MFC-dfCNT dispersions are prepared by mixing the aforementioned dfCNT-surfactant dispersions with MFC paste at a weight ratio of 5 MFC to 1 dfCNT. Mixing is done in a 100 mL beaker using an overhead stirrer equipped with a high shear impeller blade operating at 600-1200 RPM for 30 minutes.

The MFC-dfCNT composition can be added as a component of a typical Li ion battery anode paste either directly as a mixture of the MFC-dfCNT alone or in combination with one or more surfactants. Typical surfactants could be CMC, PSS, polyacrylic acid, lithiated polyacrylic acid, sodium alginate, partially lithiated sodium alginate, and others. Depending on the particular composition of the anode paste (graphite, silicon-graphite, silicon nanoparticle and other) and the form of MFC-dfCNT (dfCNT with no surfactant, dfCNT with surfactant and type of surfactant) it is possible to add the MFC-dfCNT at various point in the slurry making process. For example, with common binder components of lithium anode materials (such as CMC, SBR, polyacrylates, alginates, amide-imides, siloxanes, and urethanes), the MFC-dfCNT can be added by different routes such as: 1) with the graphite, 2) with, or as part of the CMC dispersion that is added to the graphite, 2) just prior to the addition of SBR, 3) with, or as part of the SBR dispersion that is typically added near the end of the paste making process, or 4) with, or as part of the PAA binder.

### General Process to Produce Discrete Carbon Nanotubes

A mixture of about 0.5% to about 5% carbon nanotubes, preferably 2%, by weight is prepared with CNano grade Flotube 9000 carbon nanotubes and 65% nitric acid. While stirring, the acid and carbon nanotube mixture is heated to 70 to 90 degrees Centigrade for 2 to 4 hours. The oxidized carbon nanotubes are then isolated from the acid mixture. Several methods can be used to isolate the oxidized carbon nanotubes, including but not limited to centrifugation, filtration, mechanical expression, decanting and other solid-liquid separation techniques. The residual acid is then removed by washing the oxidized carbon nanotubes with an aqueous medium such as water, preferably deionized water, to a pH of 3 to 4. The carbon nanotubes are then suspended in water at a concentration of 0.5% to 4%, preferably 1.5% by weight. The solution is subjected to intensely disruptive forces generated by shear (turbulent) and/or cavitation with process equipment capable of producing energy densities of 10⁶ to 10⁸ Joules/m³. Equipment that meet this specification includes but is not limited to ultrasonicators, cavitators, mechanical homogenizers, pressure homogenizers and microfluidizers (Table 2). After shear processing, the oxidized carbon nanotubes are discrete and individualized carbon nanotubes. Typically, based on a given starting amount of entangled as-received and as-made carbon nanotubes, a plurality of discrete oxidized carbon nanotubes results from this process, preferably at least about 60%, more preferably at least about 75%, most preferably at least about 95% and as high as 100%, with the minority of the tubes, usually the vast minority of the tubes remaining entangled, or not fully individualized.

TABLE 2

| Homogenizer | | Energy Density |
|---|---|---|
| Type | Flow Regime | (J -m⁻³) |
| Stirred tanks | turbulent inertial, turbulent viscous, | 10³-10⁶ |
| | laminar viscous | |
| Colloid mil | laminar viscous, turbulent viscous | 10³-10⁸ |
| Toothed - disc | turbulent viscous | 10³-10⁸ |
| disperser | | |
| High pressure | turbulent inertial, turbulent viscous, | 10⁶-10⁸ |
| homogenizer | cavitation inertial, laminar viscous | |
| Ultrasonic probe | cavitation inertial | 10⁶-10⁸ |
| Ultrasonic jet | cavitation inertial | 10⁶-10⁸ |
| Microfluidization | turbulent inertial, turbulent viscous | 10⁶-10⁸ |
| Membrane and | Injection spontaneous transformation | Low 10³ |
| microchannel | based | |

Excerpted from Engineering Aspects of Food Emulsification and Homogenization, ed. M Rayner and P. Dejmek, CRC Press, New York 2015.

### Example 1. Lithium Ion Anode Comprising Nanoparticles, Microfibrils and Bulk Particles

A system consisting of 10% by weight of Si nanoparticles (sourced from Sigma Aldrich), is combined with 1% by weight of MFC (obtained from commercial source: Wiedemann or Borregard) and 1% by weight of dfCNT dispersed in water by mixing with a paint-blending blade operated by overhead stirrer at 500 RPM. After stirring for 1 hr, the solution is allowed to rest, settle under gravity for 24 hrs, and excess water is decanted. The resulting Si-MFC-dfCNT suspension, is added to Graphite (86% by weight) combined with 1% wt. Na-CMC (Walocel) and stirred for 30 minutes. The 1% by weight of latex styrene butadiene, SBR (TRD-104A obtained from JSR-Micro) binder is then added to the slurry and stirred for additional 15 minutes. The resulting slurry is cast with doctor-blade setup with thickness of 100 um on copper foil and allowed to evaporate water at room temperature. Once the drying process is complete, the paste is pressed through calender double roller to reduce thickness to 60% of the original as-cast thickness. Subsequently the disc is cut from the foil and mounted into coin cell housings with a separator and NMC cathode disc. The resulting electrochemical coin cell is filled with LP-71 electrolyte (obtained from BASF) and tested for cycle life capacity and rate performance. The coin cell with addition of MFC and dfCNT gave higher capacity retention per cycle at room temperature than the control made similarly but without MFC and dfCNT.

1. A composition for an energy storage device or collection device comprising: discrete functionalized carbon nanotubes attached to microfibrillated fibers.

2. The composition of claim 1 wherein the discrete functionalized carbon nanotubes are attached to the microfibrillated fibers covalently, ionically or electrostatically.

3. The composition of claim 1 wherein a plurality of the discrete carbon nanotubes are open ended.

4. The composition of claim 1, wherein the microfibrillated fibers comprise microfibrillated organic microfibers.

5. The composition of claim 1, wherein a plurality of the microfibrillated fibers have a length from about 0.05 micrometers to about 1000 micrometers.

6. The composition of claim 5, wherein a plurality of the microfibrillated fibers are at least about 10 times the average length of the discrete carbon nanotubes.

7. The composition of claim 1, wherein the composition further comprises a nanoparticle.

8. The composition of claim 7, wherein the nanoparticle is electroactive.

9. The composition of claim 8, wherein the electroactive nanoparticle comprises a lithium intercalating compound or a lithium alloying compound.

10. The composition of claim 7, wherein the nanoparticle comprises a magnetic particle.

11. The composition of claim 7, wherein the nanoparticle comprises a catalyst.

12. The composition of claim 7, wherein the nanoparticle comprises a photoactive particle.

13. The composition of claim 7, wherein the nanoparticle is electroconductive.

14. The composition of claim 1, further comprising a polymer.

15. The composition of claim 1, further comprising an electrolyte.

16. The composition of claim 1, further comprising a surfactant selected from the group consisting of anionic, cationic, non-ionic and zwitterionic surfactants.

17. The composition of claim 14, wherein the polymer is electron or ionically conducting.

18. The composition of claim 14, wherein the polymer comprises at least one thermoset.

19. The composition of claim 14, wherein the polymer comprises at least one thermoplastic polymer, at least one thermoplastic elastomer, or a combination thereof.

20. The composition of claim 19, wherein the composition comprises a film or membrane.

21. The composition of claim 19, wherein the composition comprises a fiber or thread or a filament.

22. The composition of claim 1, wherein the discrete functionalized carbon nanotubes comprise a functionalization comprising oxygen species selected from the group consisting of carboxylic acids, phenols, aldehydes, lactols, lactones, ketone, ether linkages, and combinations thereof.

23. The composition of claim 1, wherein the discrete functionalized carbon nanotubes comprise a functionalization which includes attachment of solid electrolyte interface modifiers selected from the group consisting of carbonates, fluorides, phosphates, salicylates, oxides, hydroxides, amides, sulfates, nitrates, and combinations thereof.

24. The composition of claim 1, wherein the discrete functionalized carbon nanotubes comprise a functionalization which includes attachment of dyes.

25. The composition of claim 1, wherein the discrete functionalized carbon nanotubes comprise a functionalization which includes a metal.

26. The composition of claim 1, further comprising carbon allotropes.

27. The composition of claim 26, wherein the carbon allotropes are selected from the group consisting of graphene, graphite, graphene oxide, carbon black, non-discrete carbon nanotubes, fullerenes, and combinations thereof.

28. The composition of claim 1 dispersed in a fluid medium.

29. The composition of claim 28, wherein the fluid medium comprises an aqueous fluid.

30. The composition of claim 28, wherein the fluid medium comprises a non-aqueous fluid.

31. An electrode paste comprising the composition of claim 1.

32. A conductive ink comprising the composition of claim 1.

33. An electromagnetic shielding composite comprising the composition of claim 1.

34. A sensor comprising the composition of claim 1.

35. An energy storage device or collection device comprising a composition, the composition comprising: microfibrillated cellulose, nanoparticles and microparticles.

36. The energy storage device or collection device of claim 35, wherein a plurality of the nanoparticles have at least one dimension in the size range from about 2 to 1000 nanometers.

37. The energy storage device or collection device of claim 35, wherein a plurality of the microparticles have at least one dimension in the size range from about 1 to about 25 micrometers.

38. The energy storage device or collection device of claim 35, wherein the nanoparticles comprise electroactive particles.

39. The energy storage device or collection device of claim 35, wherein the nanoparticles comprise photoactive particles.

40. The energy storage device or collection device of claim 35, wherein the nanoparticles comprise magnetoactive particles.

41. The energy storage device or collection device of claim 35, wherein the nanoparticles are selected from the group consisting of lithium ion intercalating compounds, lithium ion alloying compounds, and lithium ion reactive particles.

42. The energy storage device or collection device of claim 35, wherein the nanoparticles comprise electroconductive particles.

43. The energy storage device or collection device of claim 35, wherein the microparticles are carbon allotropes selected from the group consisting of graphite, graphene, graphene oxide, reduced graphene oxide, carbon black, oxidized carbon black, non-discrete carbon nanotubes, fullerenes, and combinations thereof.

44. The energy storage device or collection device of claim 35, wherein the composition is dispersed in a fluid.

45. The energy storage device or collection device of claim 35, wherein the composition comprises a paste.

46. The energy storage device or collection device of claim 35, wherein the composition is in an anode or cathode.

47. The energy storage device or collection device of claim 35, wherein the microfibrillated cellulose, nanoparticles and microparticles are attached.

48. The energy storage device or collection device of claim 35, wherein the microfibrillated cellulose, nanoparticles and microparticles are unattached.

49. A composition useful in an energy storage device or collection device, the composition comprising: microfibrillated cellulose, nanoparticles and microparticles.
